(19) United States
(12) Patent Application Publication
(10) Pub. No.: US 2020/0296821 A1
(43) Pub. Date: Sep. 17, 2020

(54) Reducing Capacitive Coupling On Metal Core Boards

(71) Applicant: Signify Holding B.V., Amsterdam (NL)

(72) Inventors: John Trublowski, Troy, MI (US); Raymond Janik, Fayetteville, GA (US); Rajen Modi, Senoia, GA (US); Nilay Natwar Mehta, Peachtree City, GA (US); Sridhar Reddy Nimma, Cumming, GA (US)

(21) Appl. No.: 16/814,792

(22) Filed: Mar. 10, 2020

Related U.S. Application Data
(60) Provisional application No. 62/816,669, filed on Mar. 11, 2019.

(51) Int. Cl. H05K 1/02; H05K 1/05; H05K 1/18

(52) U.S. Cl. CPC H05K 1/0218; H05K 1/056; H05K 1/181; H05K 2201/10106; H05K 2201/0715; H05K 2201/0195; H05K 2201/10363

(57) ABSTRACT

A metal core board assembly can include a metal base layer upon which at least one electrical component is disposed. The metal core board assembly can also include a circuit assembly disposed proximate to the metal base layer, where the circuit assembly is isolated from the metal base layer, where the circuit assembly is electrically coupled to the at least one electrical component. Separating the circuit assembly from the metal base layer can reduce effects of capacitive coupling on the circuit assembly.

### CROSS-REFERENCE TO RELATED APPLICATIONS

This application claims priority under 35 U.S.C. § 119 to U.S. Provisional Patent Application Ser. No. 62/816,669, titled “Reducing Capacitive Coupling on Metal Core Boards” and filed on Mar. 11, 2019, the entire contents of which are hereby incorporated herein by reference.

### TECHNICAL FIELD

Embodiments described herein relate generally to electrical devices such as light fixtures, and more particularly to systems, methods, and devices for improving the performance and functionality of metal core boards used in such electrical devices.

### BACKGROUND

Electrical devices, such as light fixtures, often include one or more circuit boards on which multiple components (e.g., integrated circuits, resistors, diodes, transistors, hardware processors, capacitors, sensors) are disposed. There are a number of different types of circuits boards, including but not limited to printed circuit boards and metal core circuit boards, and there can be multiple divisions within each type of circuit board. Each type of circuit board has advantages and disadvantages. One common disadvantage of a metal core board (also called, among other names, a metal core circuit board, a metal core PCB, and an insulated metallic substrate circuit board) is capacitive coupling, which facilitates electronic noise, causes poor voltage and current regulation, and causes an unstable electrical environment for the components on the metal core board.

### SUMMARY

In general, in one aspect, the disclosure relates to a metal core board assembly that includes a metal base layer upon which at least one electrical component is disposed. The metal core board assembly can also include a circuit assembly disposed proximate to the metal base layer, where the circuit assembly is isolated from the metal base layer, where the circuit assembly is electrically coupled to the at least one electrical component. Separating the circuit assembly from the metal base layer can reduce effects of capacitive coupling on the circuit assembly.

These and other aspects, objects, features, and embodiments will be apparent from the following description and the appended claims.

### BRIEF DESCRIPTION OF THE DRAWINGS

The drawings illustrate only example embodiments of devices and methods for reducing capacitive coupling and shielding small signal circuits on multi-layer metal core boards and are therefore not to be considered limiting of its scope, as devices and methods for reducing capacitive coupling on metal core boards may admit to other equally effective embodiments. The elements and features shown in the drawings are not necessarily to scale, emphasis instead being placed upon clearly illustrating the principles of the example embodiments. Additionally, certain dimensions or positions may be exaggerated to help visually convey such principles. In the drawings, reference numerals designate like or corresponding, but not necessarily identical, elements.

FIG. 1 shows an exploded view of a light fixture with a circuit board assembly currently used in the art.

FIG. 2 shows a cross-sectional side view of a metal core circuit board assembly currently used in the art.

FIGS. 3A and 3B show a top view and a cross-sectional side view, respectively, of a metal core circuit board assembly in accordance with certain example embodiments.

FIGS. 4A and 4B show a top view and a cross-sectional side view, respectively, of another metal core circuit board assembly in accordance with certain example embodiments.

FIG. 5 shows a cross-sectional side view of yet another metal core circuit board assembly in accordance with certain example embodiments.

FIGS. 6A and 6B show a top view and a cross-sectional side view, respectively, of still another metal core circuit board assembly in accordance with certain example embodiments.

FIGS. 7A and 7B show a top view and a cross-sectional side view, respectively, of yet another metal core circuit board assembly in accordance with certain example embodiments.

FIGS. 8A and 8B show a top view and a cross-sectional side view, respectively, of still another metal core circuit board assembly in accordance with certain example embodiments.

FIG. 9 shows a top view of a metal core circuit board assembly that is a physical representation of the metal core circuit board assembly of FIG. 8 in accordance with certain example embodiments.

### DETAILED DESCRIPTION OF EXAMPLE EMBODIMENTS

The example embodiments discussed herein are directed to systems, methods, and devices for reducing capacitive coupling on metal core boards in electrical devices. Such electrical devices can include light fixtures. In such a case, example embodiments can be used with any type of light fixture. For instance, example devices can be used with new light fixtures or retrofitted to existing light fixtures. Further, light fixtures with which example embodiments can be used can be located in any environment (e.g., indoor, outdoor, high humidity, low temperature, sterile, high vibration).

Further, light fixtures described herein can use one or more of a number of different types of light sources, including but not limited to light-emitting diode (LED) light sources, organic LEDs, fluorescent light sources, organic LED light sources, incandescent light sources, and halogen light sources. Therefore, light fixtures described herein should not be considered limited to having a particular type of light source. When a light fixture described herein uses LED light sources, those LED light sources can include any type of LED technology, including, but not limited to, chip on board (COB) and discrete die.

A light fixture described herein can be any type fixture, including but limited to a street light, a troffer, a down can fixture, an under cabinet light fixture, a pendant light, a table lamp, a floodlight, a spot light, and a high-bay fixture. Also, example embodiments can be used with electrical devices other than light fixtures. Specifically, any electrical device that includes a circuit board can use example devices described herein. Examples of such electrical devices can include, but are not limited to, a computer (e.g., a desktop, a laptop, a tablet), a stereo, a control panel, a digital display, a television set, an appliance (e.g., a clothes dryer, a dish washing machine, a toaster, an oven), and a motor control station.

A user may be any person that interacts with an electrical device. Examples of a user may include, but are not limited to, a homeowner, a tenant, a landlord, a property manager, an engineer, an electrician, a lineman, an instrumentation and controls technician, a consultant, a contractor, and a manufacturer's representative. Example metal core circuit boards used in electrical devices (including components thereof) described herein can be made of one or more of a number of materials, including but not limited to plastic, thermoplastic, copper, aluminum, rubber, stainless steel, and ceramic.

Capacitive coupling is the transfer of energy within an electrical network or between distant networks by means of displacement current, induced by an electric field, between two or more circuit nodes. This capacitive coupling can have an adverse effect on the operation of one or more components on a circuit board, as discussed above. Example embodiments are designed to reduce or eliminate capacitive coupling and its adverse effects.

In certain example embodiments, electrical devices (e.g., light fixtures) that include example metal core circuit boards are subject to meeting certain standards and/or requirements. For example, the National Electric Code (NEC), the National Electrical Manufacturers Association (NEMA), the International Electrotechnical Commission (IEC), the California Energy Commission (CEC), Underwriters Laboratories (UL), and the Institute of Electrical and Electronics Engineers (IEEE) set standards as to electrical enclosures (e.g., light fixtures), wiring, and electrical connections. Use of example embodiments described herein meet and/or allow the associated electrical device to meet such standards when required.

Any electrical devices (e.g., light fixtures), or components thereof (e.g., example metal core circuit boards), described herein can be made from a single piece (e.g., as from a mold, injection mold, die cast, 3-D printing process, extrusion process, stamping process, or other prototype methods). In addition, or in the alternative, an electrical device (or components thereof) can be made from multiple pieces that are mechanically coupled to each other. In such a case, the multiple pieces can be mechanically coupled to each other using one or more of a number of coupling methods, including but not limited to epoxy, welding, soldering, etching, fastening devices, compression fittings, mating threads, tabs, and slotted fittings. One or more pieces that are mechanically coupled to each other can be coupled to each other in one or more of a number of ways, including but not limited to fixedly, hingedly, removeably, slidably, and threadably.

Components and/or features described herein can include elements that are described as coupling, fastening, securing, abutting, or other similar terms. Such terms are merely meant to distinguish various elements and/or features within a component or device and are not meant to limit the capability or function of that particular element and/or feature. For example, a feature described as a “coupling feature” can couple, secure, fasten, abut, and/or perform other functions aside from merely coupling.

A coupling feature (including a complementary coupling feature) as described herein can allow one or more components and/or portions of an example metal core circuit board to become coupled, directly or indirectly, to another portion of the metal core circuit board and/or a component (e.g., an enclosure wall) of the electrical device. A coupling feature can include, but is not limited to, a snap, a clamp, a portion of a hinge, an aperture, a recessed area, a protrusion, a slot, a spring clip, a tab, a detent, and mating threads. One portion of an example metal core circuit board can be coupled to another component of the metal core circuit board or another component of the electrical device by the direct use of one or more coupling features.

In addition, or in the alternative, a portion of an example metal core circuit board can be coupled to another portion of the metal core circuit board or another component of the electrical device using one or more independent devices that interact with one or more coupling features disposed on a component of the electrical device. Examples of such devices can include, but are not limited to, a pin, a hinge, a fastening device (e.g., a bolt, a screw, a rivet), epoxy, a sealing member (e.g., an O-ring, a gasket), glue, adhesive, tape, and a spring. One coupling feature described herein can be the same as, or different than, one or more other coupling features described herein. A complementary coupling feature (also sometimes called a corresponding coupling feature) as described herein can be a coupling feature that mechanically couples, directly or indirectly, with another coupling feature.

If a component of a figure is described but not expressly shown or labeled in that figure, the label used for a corresponding component in another figure can be inferred to that component. Conversely, if a component in a figure is labeled but not described, the description for such component can be substantially the same as the description for the corresponding component in another figure. The numbering scheme for the various components in the figures herein is such that each component is a three-digit number, and corresponding components in other figures have the identical last two digits. For any figure shown and described herein, one or more of the components may be omitted, added, repeated, and/or substituted. Accordingly, embodiments shown in a particular figure should not be considered limited to the specific arrangements of components shown in such figure.

Further, a statement that a particular embodiment (e.g., as shown in a figure herein) does not have a particular feature or component does not mean, unless expressly stated, that such embodiment is not capable of having such feature or component. For example, for purposes of present or future claims herein, a feature or component that is described as not being included in an example embodiment shown in one or more particular drawings is capable of being included in one or more claims that correspond to such one or more particular drawings herein.

Example embodiments of reducing capacitive coupling and shielding of small signal circuits on metal core boards in electrical devices be described more fully hereinafter with reference to the accompanying drawings, in which example embodiments of reducing capacitive coupling on metal core boards in electrical devices are shown. Reducing capacitive coupling on metal core boards in electrical devices may, however, be embodied in many different forms and should not be construed as limited to the example embodiments set forth herein. Rather, these example embodiments are provided so that this disclosure will be thorough and complete, and will fully convey the scope of reducing capacitive coupling on metal core boards in electrical devices to those or ordinary skill in the art. Like, but not necessarily the same, elements (also sometimes called components) in the various figures are denoted by like reference numerals for consistency.

Terms such as “first”, “second”, “top”, “bottom”, “outer”, “inner”, “height”, “width”, thickness”, “lower”, “upper”, “side”, “front”, “distal”, “proximal”, and “within” are used merely to distinguish one component (or part of a component or state of a component) from another. Such terms are not meant to denote a preference or a particular orientation. Such terms are not meant to limit embodiments of reducing capacitive coupling on metal core boards in electrical devices. In the following detailed description of the example embodiments, numerous specific details are set forth in order to provide a more thorough understanding of the invention. However, it will be apparent to one of ordinary skill in the art that the invention may be practiced without these specific details. In other instances, well-known features have not been described in detail to avoid unnecessarily complicating the description.

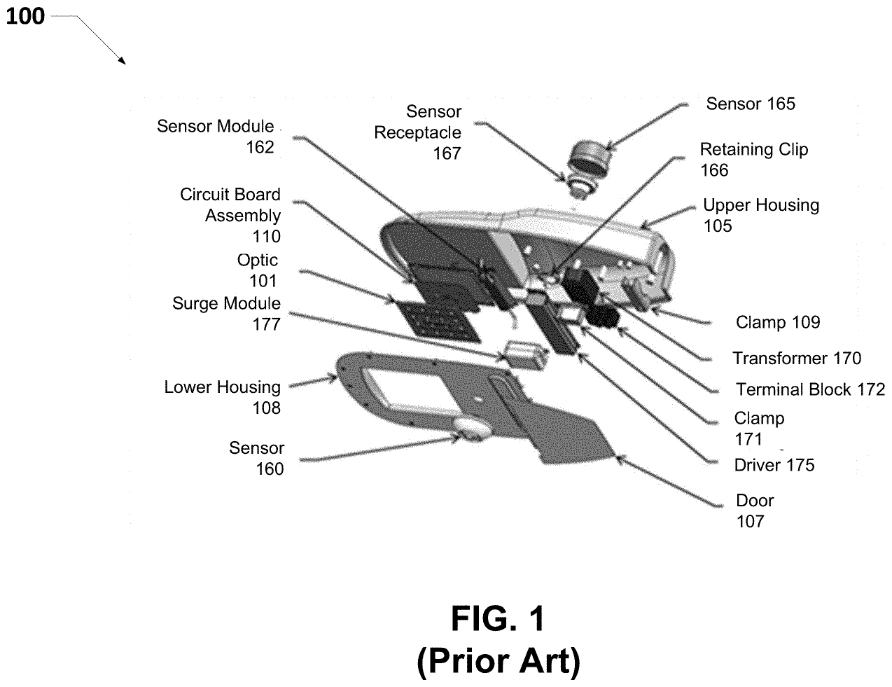

FIG. 1 shows an exploded view of a light fixture 100 with a circuit board assembly 110 currently used in the art. As discussed above, the light fixture 100 is a type of electrical device. In this case, the light fixture 100 of FIG. 1 is a street light. In addition to the circuit board assembly 110, the light fixture 100 of FIG. 1 includes an upper housing 105 that is coupled to a lower housing 108 and a door 107. Disposed within a cavity formed by the upper housing 105, the lower housing 108, and the door 107 is the circuit board assembly 110, an optic 101, a sensor module 162, a retaining clip 166 for the sensor module 162, a driver 175 (a form of power supply), a transformer 170, a clamp 171 for the transformer 170, a terminal block 172, a surge module 177, and a clamp 109 for a pole (not shown) for mounting. A sensor 160 is disposed on an outer (bottom) surface of the lower housing 108, and another sensor 165 is disposed on an outer (upper) surface of the upper housing 105. A sensor receptacle 167 can be used to couple the sensor 165 to the upper housing 105.

The circuit board assembly 110 can include one or more of a number of components. Among these components is a circuit board. As discussed above, the circuit board of the circuit board assembly 110 can have any of a number of configurations and be made of any of a number of materials. A circuit board can have any of a number of layers and/or have any of a number of substrates disposed thereon. In addition to the circuit board, the circuit board assembly 110 can include one or more of a number of different components (e.g., integrated circuits, resistors, diodes, transistors, hardware processors, capacitors, sensors, heat sinks, terminal blocks) disposed on the circuit board.

In this case, where the electrical device is a light fixture 100, particularly using LED technology, such luminaires typically consist of an assembly of mechanical and electrical components. The components of the light fixture 100 shown in FIG. 1 typically are packaged as independent units, each having their own support electronics, connector interfaces, wire harnesses, and mechanical housings. The light fixture 100 is assembled by using multiple coupling features (e.g., fasteners, clamps) to attach these various components to each other. One or more of these components of the light fixture 100 are also coupled to an outer housing (which in this case includes the upper housing 105, the lower housing 108, and the door 107).

To interconnect the various electrical/electronic sub-assemblies, numerous internal wiring harnesses with connectors are required. To minimize the number of connections and associated mechanical housings, integration of many components into a single sub-assembly is desirable. The benefits associated with this approach include a lower number of components, lower cost of assembly, and improved electrical/electronic performance and reliability. The circuit board assembly 110 is a principal way to embody this integration and achieve these benefits. When the circuit board of the circuit board assembly 110 includes metal or is a metal core circuit board, capacitive coupling can result, resulting in electronic noise, poor voltage and current regulation, and an unstable electrical environment for the components mounted on the circuit board.

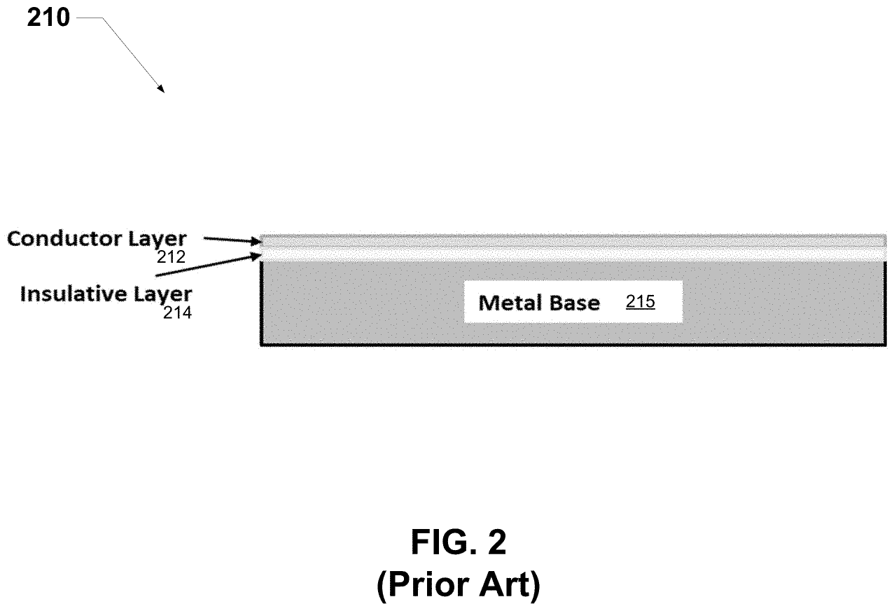

FIG. 2 shows a cross-sectional side view of a metal core circuit board assembly 210 currently used in the art. Referring to FIGS. 1 and 2, the metal core circuit board assembly 210 of FIG. 2 includes a metal base 215, on top of which is disposed an insulative layer 214 (also called an insulative substrate 214 and a dielectric layer 214), on top of which is disposed a conductive layer 212 (also called a conductive substrate 212). While the insulative layer 214 and the conductive layer 212 can have thermal properties (e.g., thermally conductive, thermally non-conductive), the insulative layer 214 is designed to electrically isolate the conductive layer 212 from the metal base 215. Further, the conductive layer 212 can be designed to be electrically conductive.

Since the metal base 215 is made, at least in part, of metal, the metal base 215 is designed to be electrically conductive. The metal base 215 can also be thermally conductive. In fact, thermal management is one principal reason for using a metal core board, as some components (e.g., resistors, diodes, integrated circuits, driver circuitry) disposed, directly or indirectly, on a circuit board (e.g., metal base 215) can operate at higher temperatures, which can adversely affect the performance and longevity of adjacent components on the circuit board. The metal base 215 acts as a very large and effective heat sink to absorb heat generated by such heat-generating components disposed on the conductive layer 212 and subsequently dissipate that heat away from those heat-generating components. Other reasons for using the metal base 215 can include improved stability (e.g., structural integrity), a reduced footprint, higher packing density, more stable operating parameters, higher operational safety, and a reduced failure rate of electrical components.

With these benefits of using metal core boards (a name used herein for circuit board assemblies that include a metal base 215), there are also some drawbacks. For example, a common problem that occurs with metal core boards is capacitive coupling (also called parasitic capacitance) generated between switching that occurs on the circuit board assembly, relatively high voltage power that can commonly be used, and the interaction of those factors with the metal base 215. The result is induced current into the low voltage circuitry (used in the control circuits) of the circuit board assembly that generates noise at the outputs of and within the circuit board assembly.

As a more specific explanation, using the metal base 215 for driver circuitry (and other components that generate heat) is desirable because the metal base 215 provides a built-in heat sink and/or acts as a heat spreader. The insulative layer 214 provides electrical insulation and thermal conductivity between the metal base 215 and the power circuits disposed on the conductive layer 212. This configuration of the insulative layer 214 allows even dissipation in the metal base 215 of heat generated by the driver circuits and/or other heat-generating components disposed on the conductive layer 212, resulting in higher reliability and functionality compared to using polymer-based (e.g., epoxy laminate FR4) substrates.

For metal core circuit board assemblies 210, it is desirable to have the insulative layer 214 separating the conductive layer 212 (on which the circuitry is disposed) and the metal base 215 to be as thin as possible (e.g., 50 μm-200 μm) to minimize thermal impedance of the insulative layer 214. However, because of the layered structure of the metal core circuit board assembly 210 shown in FIG. 2, the dielectric layer 214 and the metal base 215 electrically form a capacitor. Because the dielectric layer 214 is thin, capacitive coupling between the metal base 215 and the components disposed atop the conductive layer 212 can occur if high speed switching of power is functionally realized.

This parasitic capacitance is observed at the output of the driver (or other power supply) in the form of electronic noise generation, which decreases the efficiency of the circuit disposed atop the conductive layer 212 to power the LED's or other load of the electrical device. In many cases, this noise has inhibited or prevented the integration of the power supply and the associated electrical load using a metal base 215 for the circuit board assembly 210. By contrast, in polymer-based boards (e.g., FR4) used as a base, there may be capacitive coupling in a localized area only near the traces through which the high power flows. For the metal base 215, the parasitic capacitance couples the entire metal substrate to the whole power supply (e.g., driver circuit).

A typical circuit integrating these functions consists of a high voltage section and a small signal control section, both of which are on the primary input side of the power supply (e.g., driver). The switched high voltage of the power supply induces current spikes in nearby traces due to the parasitic capacitance between the high voltage switched node and any conductive trace near it. The presence of the electrically-conductive metal in the metal base 215 spreads this effect through the entire metal base 215, not just the nearby traces. The resulting induced current is injected into the small signal control circuit, which masks the small signal (on the order of millivolts) or induces false signals. This results in poor regulation and unstable output. Example embodiments shown and described herein greatly reduce or eliminate parasitic capacitance, thereby also reducing or eliminating the adverse effects caused by such parasitic capacitance.

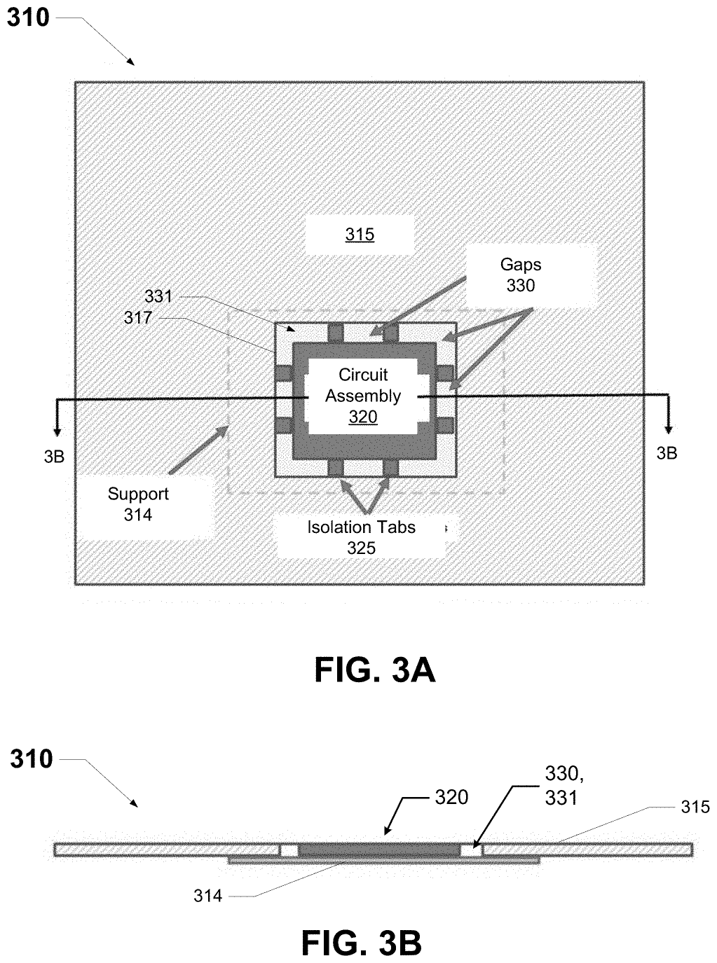

FIGS. 3A and 3B show a top view and a cross-sectional side view, respectively, of a metal core circuit board assembly 310 in accordance with certain example embodiments. Referring to FIGS. 1 through 3B, the metal core circuit board assembly 310 of FIGS. 3A and 3B include a metal base 315 that has an aperture 331 that traverses the thickness of part (in this case, the approximate lower middle) of the metal base 315. The aperture 331 is defined by an edge 317 of the metal base 315 and in this case is the shape of a rectangle, although the aperture 331 can have any of a number of other shapes (e.g., circle, triangle, square, hexagon, random). In some cases, there can be multiple apertures 331.

Disposed within the aperture 331 is a circuit assembly 320. The circuit assembly 320 has a width (when viewed from above) that is less than the width of the aperture 331 formed by the edge 317. Similarly, the circuit assembly 320 also has a height (when viewed from above) that is less than the height of the aperture 331 formed by the edge 317. In this way, the circuit assembly 320 can fit entirely within the aperture 331 without making physical contact with any of the edge 317. The shape of the circuit assembly 320 can be the same as, or different than, the shape of the aperture 331 defined by the edge 317. In any case, the circuit assembly 320 is positioned in such a way within the aperture 331 as to avoid making any direct physical contact with the metal base 315. Specifically, there are gaps 330 that are formed between the circuit assembly 320 and the metal base 315.

Disposed between the circuit assembly 320 and the metal base 315 can be one or more isolation tabs 325, which each make a connection between the circuit assembly 320 and the metal base 315. These isolation tabs 325 can be formed in any of a number of ways, including but not limited to with tooling when the outline of the metal base 315 and the aperture 331 are punched to their shape, punched in a secondary operation, or separately machined. An isolation tab 325 can also be an electrical conductor, with one end coupled to a component disposed on or part of the metal base 315, and with the other end coupled to the circuit assembly 320 (or component thereof).

The isolation tabs 325 can be permanent or temporary (e.g., removable). In practice, the circuitry of the metal base 315 and the circuit assembly 320 can be configured relative to each other in any of a number of ways. For example, the circuitry of the metal base 315 and the circuit assembly 320 can be formed using standard PCB methods, where thin copper (or similar electrically-conductive metal) foil is laminated to the base substrate (e.g., the metal base 315, the circuit board of the circuit assembly 320) and then chemically etched (subtractive process) to form the circuit traces.

Alternatively, an additive process can be used by printing layers (e.g., screen, ink jet, aerojet, flexographic, printing) of dielectric and electrically-conductive materials. Typically, the printing step is followed by a film drying step (to remove inorganic solvents and vehicles), and then a firing step (at high temperature) to sinter the inorganic constituents of the ink together, thereby forming a continuous film while creating a metallurgical bond with the substrate. Any of these various methods of applying one or more layers directly or indirectly atop a metal base (e.g., metal base 315) can be used in any of the example embodiments described herein. Once the metal base 315 and/or the circuit board of the circuit assembly 320 is fabricated with the circuit traces, components can then be placed (electrically attached using solder, electrically-conductive adhesive, or some other method) on the metal base 315 and/or the circuit board. At this point, the isolation tabs 325 can be removed.

The circuit board assembly 310 can also include an optional support 314 mounted on a bottom surface of the metal base 315. The support 314 is designed to help anchor the circuit assembly 320 relative to the metal base 315 within the aperture 331. The support 314 can have any of a number of forms and configurations. For example, in this case, the support 314 is a solid, electrically non-conductive layer that covers the aperture 331. As another example, the support 314 can be an electrically non-conductive mesh that covers the aperture 331.

As still another example, the support 314 can be an electrically insulative tape or film that can be adhesively bonded, molded, printed (using dielectric inks), or otherwise disposed on the circuit assembly 320 and at least portions of the metal base 315. In any case, if the support 314 exists, it is coupled to both the circuit assembly 320 (in this case, on the back side) and at least the portions of the metal base 315 (also on the back side in this case) adjacent to the aperture 331. In addition to being electrically non-conductive, the support 314 can have any type of thermal property (e.g., thermally conductive, thermally non-conductive).

The circuit assembly 320 can include a control circuit that is disposed on a circuit board (e.g., another metal base 315, a polymer-based circuit board). Similarly, a power supply can be disposed on the metal base 315. The isolation tabs 325 can be coupled to the circuit board of the circuit assembly 320 or directly to one or more components disposed on the circuit board of the circuit assembly 320. As discussed above, capacitive coupling caused by the power supply can have an adverse effect on the control circuit of the circuit assembly 320 when these two circuits are mounted on the same metal base 315. By using the system and method for physically and, aside from the isolation tabs 325, electrically isolating the circuit assembly 320 from the rest of the metal base 315, the adverse effects associated with capacitive coupling can be greatly reduced or eliminated.

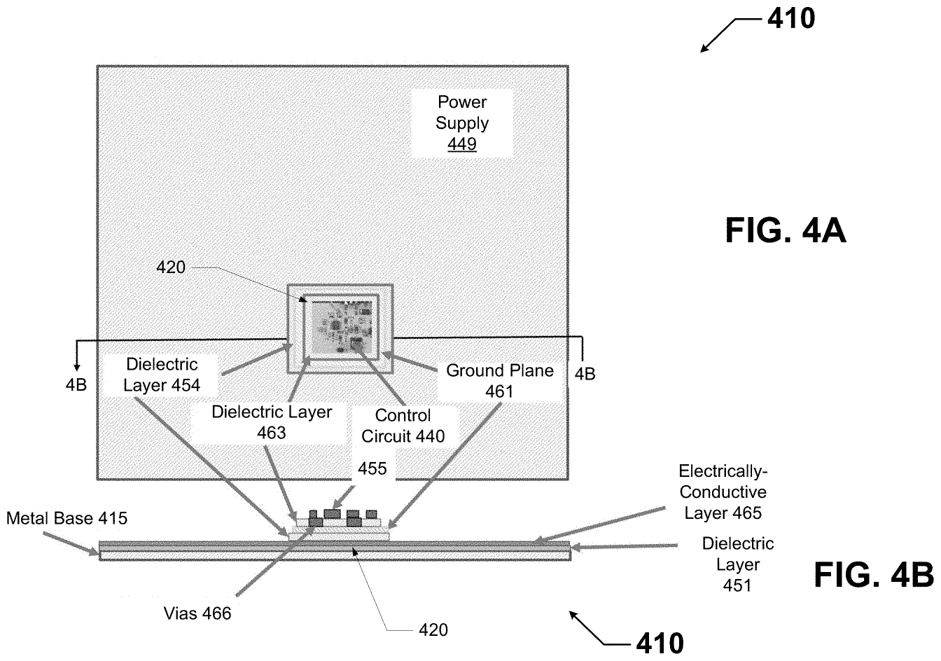

FIGS. 4A and 4B show a top view and a cross-sectional side view, respectively, of another metal core circuit board assembly 410 in accordance with certain example embodiments. Referring to FIGS. 1 through 4B, the metal core circuit board assembly 410 of FIGS. 4A and 4B shows an example where there is no aperture (such as aperture 331 of FIG. 3) in the metal base 415 for receiving the circuit assembly 420. Instead, isolation and shielding of the circuit assembly 420 is achieved by using a number of dielectric layers and a printed electrically-conductive ground plane 461.

The metal core circuit board assembly 410 of FIGS. 4A and 4B includes the metal base 415 (e.g., aluminum), in this case having no aperture (e.g., aperture 331) that traverses the thickness of the metal base 415. As a result, there is no support (e.g., support 314) that is coupled to the bottom surface of the metal base 415. In addition, there are multiple layers disposed atop the metal base 415 that were not disposed atop the metal base 315 of FIGS. 3A and 3B. Specifically, dielectric layer 451 (also called an isolation plane 451) is disposed atop the entire metal base 415. Also, an electrically-conductive layer 465 is disposed atop the entire dielectric layer 451.

In certain alternative embodiments, an optional secondary isolation plane (similar to dielectric layer 451) can be added on top of the dielectric layer 451 to increase the dielectric thickness and minimize or limit capacitive coupling. As an example, this additional isolation plane could be printed with a low temperature, polymer-based ink, and the same (or the use of different methods) could be done for the successive layers. The circuit assembly 420 is disposed atop a portion of the electrically-conductive layer 465, and the remainder of the electrically-conductive layer 465 has no other layers disposed atop it. Instead, the various components (e.g., resistors, diodes, integrated circuits, capacitors, transistors) of the power supply 449 (also sometimes called a power circuit 449) are disposed atop the electrically-conductive layer 465 in areas not occupied by the circuit assembly 420.

As discussed above, the circuit assembly 420 is layered atop an isolated portion of the electrically-conductive layer 465. Specifically, disposed atop a portion of the electrically-conductive layer 465 is another dielectric layer 454. Disposed (e.g., printed) atop the second dielectric layer 454 on the portion of the electrically-conductive layer 465 that hosts the circuit assembly 420 is the electrically-conductive ground plane 461, atop of which is disposed (e.g., printed) another dielectric layer 463 (also called an isolation plane 463). Disposed (e.g., printed) within one or more portions of the dielectric layer 463 are one or more vias 466, which provide electrical connectivity between the control circuit 440 and the power supply 449.

In some cases, a via 466 is electrically conductive. In other cases, a via 466 (also called an opening 466) is electrically non-conductive but designed into the dielectric layer 463 so that an electrical conductor can be deposited into the via 466, either during a separate conductor print or while printing the electrically-conductive traces of the control circuit 440. In any case, the vias 466 provide a conductive conduit between the control circuit 440 and the electrically-conductive ground plane 461 such that the electrically-conductive ground plane 461 can be polarized (usually with a negative electrical bias), causing it to act as a ground shield and eliminate (or at least greatly reduce) any capacitive coupling to the power supply 449.

Disposed atop parts of the dielectric layer 463 and/or the vias 466 are multiple electrically-conductive traces 455. The discrete components of the control circuit 440 of the circuit assembly 420 have electrically-conductive leads that are disposed on and make contact with the traces 455, using the traces 455 as electrical conductors to carry low voltage and/or control signals. Any of the printing techniques and/or materials described herein or known in the art can apply to any of the layers of the circuit board assembly 410 of FIGS. 4A and 4B.

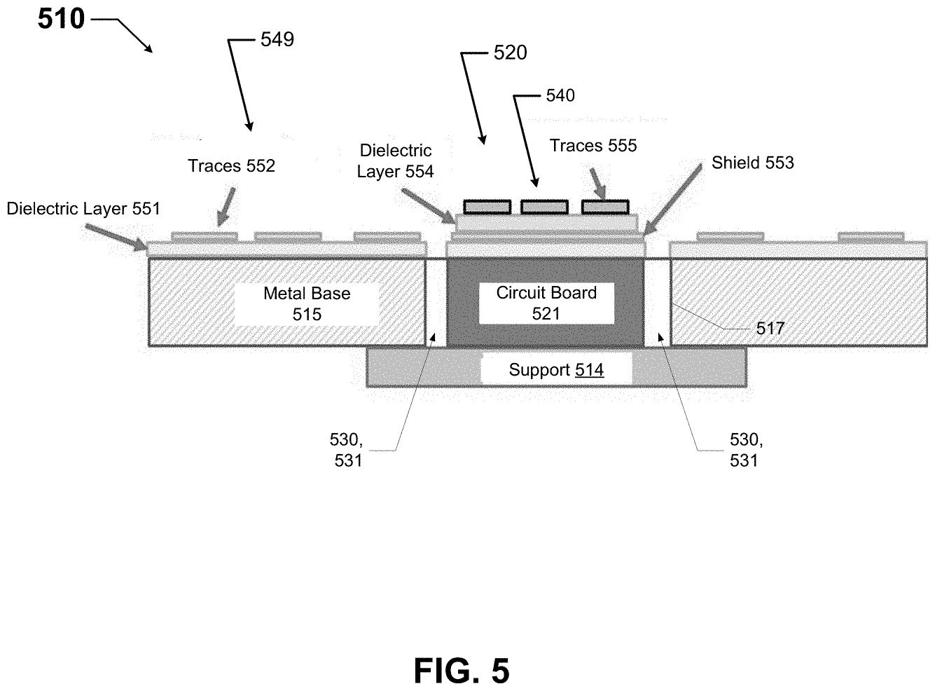

FIG. 5 shows a cross-sectional side view of yet another metal core circuit board assembly 510 in accordance with certain example embodiments. Referring to FIGS. 1 through 5, the metal core circuit board assembly 510 of FIG. 5 shows an example where a shielding plane is built using an additive process. The metal core circuit board assembly 510 (including components thereof) of FIG. 5 is similar to the metal core circuit board assembly 310 (including corresponding components thereof) of FIGS. 3A and 3B, with added features discussed below.

For example, the metal core circuit board assembly 510 of FIG. 5 includes a metal base 515 that has an aperture 531 that traverses the thickness of part (in this case, the approximate lower middle) of the metal base 515. The aperture 531 is defined by an edge 517 of the metal base 515 and in this case is the shape of a rectangle. Disposed within the aperture 531, and without physically contacting the metal base 515, is a circuit assembly 520 that includes a circuit board 521 having a rectangular shape with a width that is less than the width of the aperture 531 formed by the edge 517 and a height that is less than the height of the aperture 531 formed by the edge 517. There is a continuous gap 530 or multiple gaps 530 that are formed between the circuit assembly 520 and the metal base 515. The circuit board assembly 510 in this case also includes a support 514 (similar to support 314 of FIGS. 3A and 3B above) that is coupled to the bottom surfaces of the metal base 515 and the circuit board 521 of the circuit assembly 520.

In addition, there are multiple layers disposed atop the metal base 515 and the circuit board 521 of the circuit assembly 520. Specifically, a dielectric layer 551 is disposed atop both the metal base 515 and the circuit board 521 of the circuit assembly 520, but not in any of the gaps 530 therebetween. On top of the dielectric layer 551 on the circuit board 521 of the circuit assembly 520 is disposed a localized, electrically-conductive electronic shield 553. Disposed atop the electrically-conductive electronic shield 553 on the circuit assembly 520 is another dielectric layer 554. Finally, atop the dielectric layer 554 on the circuit assembly 520 are multiple electrically-conductive traces 555.

Disposed atop these traces 555 are the various discrete components of the control circuit 540 of the circuit assembly 520, where the traces 555 serve as electrical conductors to carry low voltage and/or control signals to and from those components of the control circuit 540. These layers of the circuit assembly 520 disposed on the circuit board 521 to not extend beyond the edges of the circuit board 521, so that the gap 530 is maintained for all of the layers.

On top of the portion of the dielectric layer 551 that is not disposed on the circuit board 521 of the circuit assembly 520 (e.g., directly atop the metal base 515) are disposed multiple electrically-conductive traces 552. Disposed atop these traces 552 are the various discrete components that make up the power supply 549, using the traces 552 as electrical conductors to carry voltage and/or control signals to and from those components of the power supply 549. Example thicknesses for these layers are 4 μm-60 μm for the dielectric layers 551 and/or 554, and 10 μm-15 μm for the electrically-conductive conductive traces 552 and/or 555. The thickness of any of these layers can be adjusted to allow for improved electrical performance (e.g., higher current carrying capability) and/or some other desired effect.

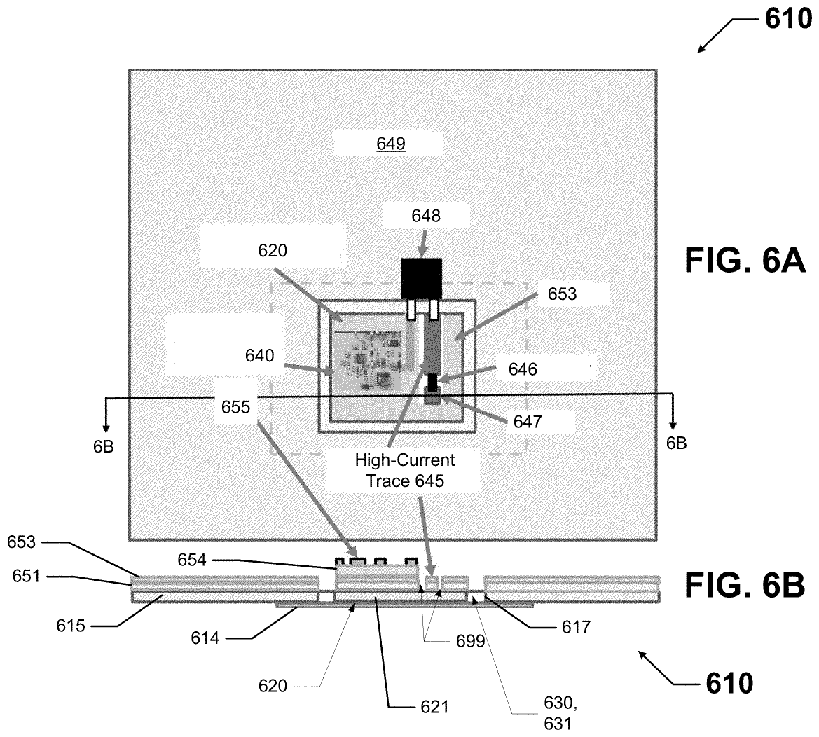

FIGS. 6A and 6B show a top view and a cross-sectional side view, respectively, of still another metal core circuit board assembly 610 in accordance with certain example embodiments. Referring to FIGS. 1 through 6B, the metal core circuit board assembly 610 of FIGS. 6A and 6B shows an example where a high-current trace 645 is integrated with the circuit assembly 620. The metal core circuit board assembly 610 (including components thereof) of FIGS. 6A and 6B is similar to the metal core circuit board assembly 510 (including corresponding components thereof) of FIG. 5, with added/different features as discussed below.

For example, the metal core circuit board assembly 610 of FIGS. 6A and 6B includes a metal base 615 that has an aperture 631 that traverses the thickness of part (in this case, the approximate lower middle) of the metal base 615. The aperture 631 is defined by an edge 617 of the metal base 615 and in this case is the shape of a rectangle. Disposed within the aperture 631, and without physically contacting the metal base 615, is a circuit assembly 620 that includes a circuit board 621 having a rectangular shape with a width that is less than the width of the aperture 631 formed by the edge 617 and a height that is less than the height of the aperture 631 formed by the edge 617. There can be one continuous gap 630 or multiple gaps 630 that are formed between the circuit assembly 620 and the metal base 615. The metal core circuit board assembly 610 in this case also includes a support 614 that is coupled to the bottom surfaces of the metal base 615 and the circuit board 621 of the circuit assembly 620.

In addition, there are multiple layers disposed atop the metal base 615 and the circuit board 621 of the circuit assembly 620. Specifically, dielectric layer 651 is disposed atop both the metal base 615 and the circuit board 621 of the circuit assembly 620, but not in any of the gaps 630 therebetween. Also, there are gaps 699 in the dielectric layer 651 atop the circuit board 621 of the circuit assembly 620. In other words, the dielectric layer 651 is not disposed over the entire top surface of the circuit board 621 of the circuit assembly 620. These gaps 699 physically separate the high-current trace 645 from the shield 653. Specifically, aside from where the high-current trace 645 is disposed atop the dielectric layer 651 on the circuit board 621 of the circuit assembly 620, a localized, electrically-conductive electronic shield 653 is disposed atop the dielectric layer 651 on the circuit board 621. The electrically-conductive electronic shield 653 is separated from the high-current trace 645 by the gaps 699.

Disposed atop the electrically-conductive electronic shield 653 on the portion of the circuit assembly 620 that includes the control circuit 640 is another dielectric layer 654. Finally, disposed atop the second dielectric layer 654 on the portion of the circuit assembly 620 that includes the control circuit 640 are multiple electrically-conductive traces 655. The discrete components of the control circuit 640 of the circuit assembly 620 have electrically-conductive leads that are disposed on and make contact with the traces 655, using the traces 655 as electrical conductors to carry low voltage and/or control signals.

These layers disposed on the circuit board 621 of the circuit assembly 620 do not extend beyond the edges of the circuit board 621, so that the gap 630 is maintained for all of the layers. Similarly, the gaps 699 that are formed at various points above the circuit board 621 of the circuit assembly 620 can be maintained vertically through all of the various layers. In this example, there are no additional layers disposed atop the electrically-conductive electronic shield 653 at some portions of the circuit assembly 620. Also, there are no additional layers disposed atop the electrically-conductive electronic shield 653 on the metal base 615 in this example.

The power supply 649 is disposed on the electrically-conductive electronic shield 653 atop the metal base 615 and is connected to the circuit assembly 620 by a power FET 648. In this example, the power FET 648 has one pin connected to the high-current trace 645 disposed (e.g., printed) within the electrically-conductive electronic shield 653 and another pin connected to a lead that connects to the control circuit 640. The distal end of the high-current trace 645 in this example is connected to a sense resistor 646, which in turn is connected to an electrically-conductive electronic shield 647, which can be the same as or different than the electrically-conductive electronic shield 653.

In some cases, the same material family for the printed electronic inks is used for all of the aforementioned layers. Certain types of printed inks are capable of carrying high current but must be processed at high temperatures. When there are multiple layered structures with these inks, the repeated high temperature processing may cause conductor ions to diffuse into the dielectric, resulting in a dielectric with poor electrical properties. In such a case, the high-temperature ink can be used to form the electrically-conductive electronic shield 653 (and any conductors requiring high current carrying capability) of the isolated circuit assembly 620.

Subsequently, the second dielectric layer 654 and conductor could be deposited using lower cure temperature materials (e.g., polymer-based electronic inks). Such materials sinter at much lower temperatures, which minimizes any diffusion. As a result, this deposition approach can be well suited for the configuration of the metal core circuit board assembly 610 shown in FIGS. 6A and 6B. One potential draw-back is that the polymer-based conductors have much higher electrical resistivity than their high temperature counterparts, and so the polymer-based conductors are best suited for low current-carrying circuits.

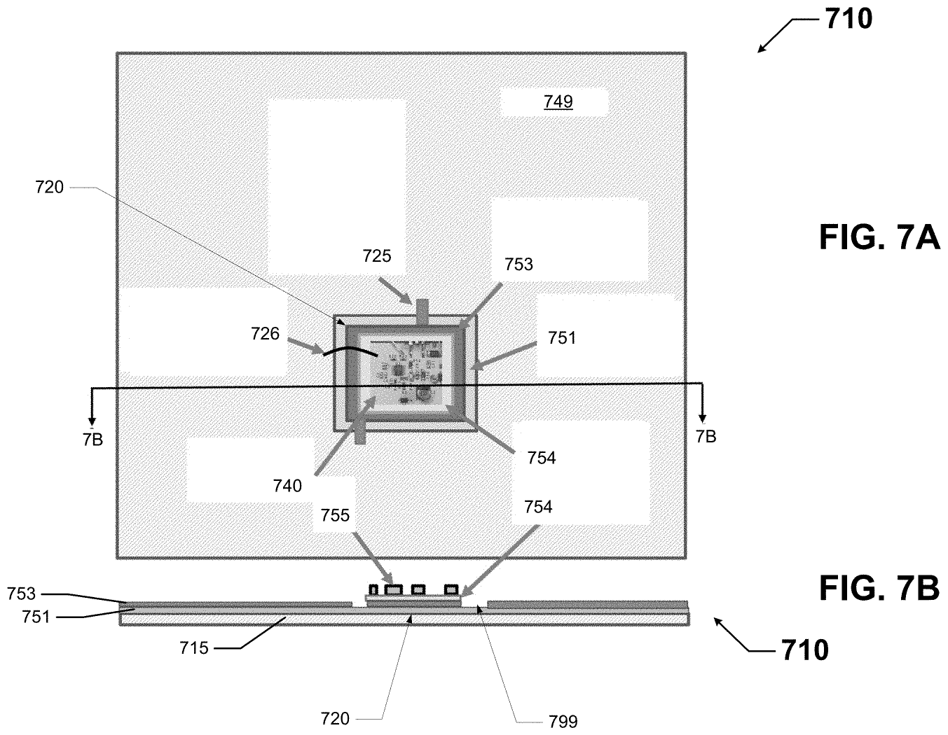

FIGS. 7A and 7B show a top view and a cross-sectional side view, respectively, of yet another metal core circuit board assembly 710 in accordance with certain example embodiments. Referring to FIGS. 1 through 7B, the metal core circuit board assembly 710 of FIGS. 7A and 7B shows an example where there is no aperture in the metal base 715 for receiving the circuit assembly 720. Instead, isolation and shielding of the circuit assembly 720 is achieved by using a dielectric layer and a printed electrically-conductive electronic shield 753. The metal core circuit board assembly 710 (including components thereof) of FIGS. 7A and 7B is similar to the metal core circuit board assemblies (including corresponding components thereof) discussed above, with added/different features as discussed below.

The metal core circuit board assembly 710 of FIGS. 7A and 7B includes the metal base 715, in this case having no aperture (e.g., aperture 631) that traverses the thickness of the metal base 715. As a result, there is no support (e.g., support 614) that is coupled to the bottom surface of the metal base 715. In addition, there are multiple layers disposed atop the metal base 715. Specifically, dielectric layer 751 is disposed atop the entire metal base 715. Also, an electrically-conductive electronic shield 753 is disposed atop the dielectric layer 751, but there are gaps 799 in the electrically-conductive electronic shield to physically separate the circuit assembly 720 from the rest of the metal base 715. In this example, there are no other layers disposed atop the electrically-conductive electronic shield 753 outside of the gaps 799 on the rest of the metal base 715.

Disposed atop the electrically-conductive electronic shield 753 on the portion of the metal base 715 that hosts the circuit assembly 720 is another dielectric layer 754. Finally, disposed atop the second dielectric layer 754 on the portion of the metal base 715 that hosts the circuit assembly 720 are multiple electrically-conductive traces 755. The discrete components of the control circuit 740 of the circuit assembly 720 have electrically-conductive leads that are disposed on and make contact with the traces 755, using the traces 755 as electrical conductors to carry low voltage and/or control signals.

In some cases, the first dielectric layer 751 is printed in the same step as the dielectric that is printed to form the power supply of the circuit assembly 720. The material of the dielectric layer 751 electrically insulates the subsequent layers from the metal base 715. Next, the electrically-conductive electronic shield 753 can be printed on top of the dielectric layer 751, including the traces (e.g., traces 755) of the power supply of the circuit assembly 720. This electrically-conductive electronic shield 753 can be electrically connected to the proper shield polarity defined in the power supply (like the negative or ground trace) during the deposition of the electrically-conductive electronic shield 753. Alternatively, the electrically-conductive electronic shield 753 can be connected using a discrete jumper later in the process.

The second dielectric layer 754 can be printed over the electrically-conductive electronic shield 753 to isolate the control circuit 740. The control circuit 740 can then be printed on top of the dielectric layer 754, and one or more jumpers 725, 726 can be used to connect the control circuit 740 to the power supply 749, the components for which are disposed on the other side of the gap 799 atop the electrically-conductive electronic shield 753. In some cases, in addition to or as an alternative to jumpers 725, 726, one or more vias (such as those shown in FIG. 4 above) can be incorporated into one or more of the multi-layered structures to provide connectivity between the control circuit 740 and the power supply 749.

As discussed above, many different materials and/or deposition techniques can be used for each layer. For example, ceramic-based materials can be used for the power supply 749, the dielectric layer 754, and the electrically-conductive electronic shield 753, while polymer-based materials can be used for the control circuit 740. One rationale for this arrangement is that the higher temperatures required for processing of the ceramic-based materials result in migration of those conductors into the dielectric layer 754, resulting in sub-optimal dielectric properties. The polymer-based materials are processed at a much lower temperature, and so they will not migrate. The main issue with the polymer-based materials is that the conductor resistivity is much higher than for the ceramic-based materials, and so the power supply 749 may be difficult to fabricate.

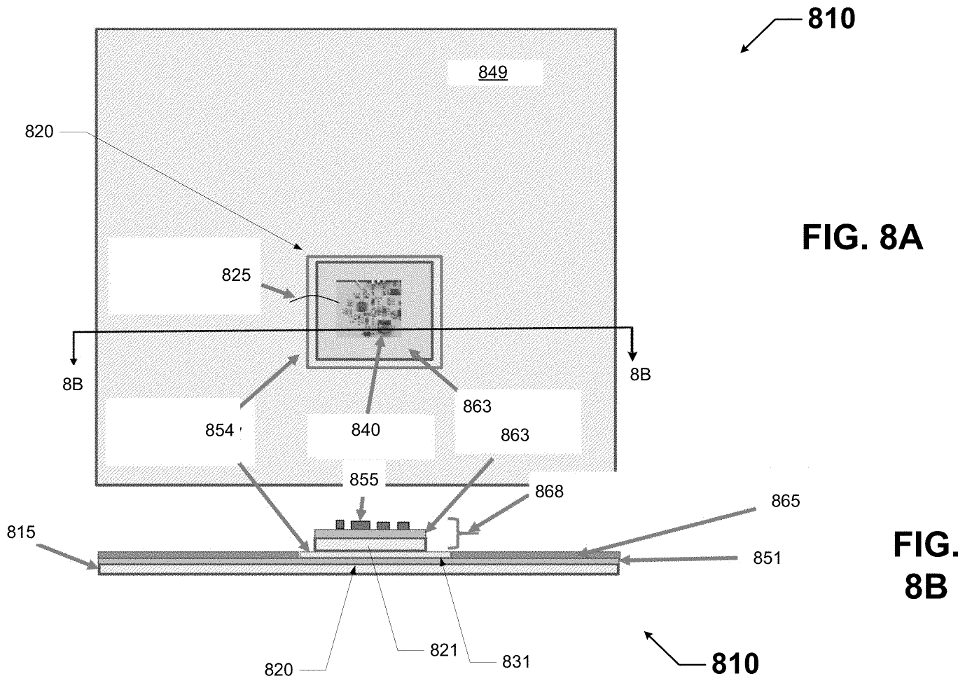

FIGS. 8A and 8B show a top view and a cross-sectional side view, respectively, of still another metal core circuit board assembly 810 in accordance with certain example embodiments. Referring to FIGS. 1 through 8B, the metal core circuit board assembly 810 of FIGS. 8A and 8B shows an example where there is no aperture in the metal base 815 for receiving the circuit assembly 820. Instead, isolation and shielding of the circuit assembly 820 is achieved by using a number of dielectric layers. The metal core circuit board assembly 810 (including components thereof) of FIGS. 8A and 8B is similar to the metal core circuit board assemblies (including corresponding components thereof) discussed above, with added/different features as discussed below.

The metal core circuit board assembly 810 of FIGS. 8A and 8B includes the metal base 815 (e.g., made of aluminum). In this example, there is no aperture (e.g., aperture 331) that traverses the thickness of the metal base 815. As a result, there is no support (e.g., support 314) that is coupled to the bottom surface of the metal base 815. In addition, there are multiple layers disposed atop the metal base 815. Specifically, dielectric layer 851 (also called an isolation plane 851) is disposed atop the entire metal base 815. Also, an electrically-conductive layer 865 is disposed atop the entire dielectric layer 851 (or at least the majority of the dielectric layer 851).

In this case, the electrically-conductive layer 865 is disposed atop all but a small area in the middle of the dielectric layer 851. In other words, there is an aperture 831 that traverses part of the electrically-conductive layer 865, inside of which the dielectric layer 854 that supports the circuit assembly 820 is disposed. As shown in FIGS. 8A and 8B, within the aperture 831 in this case is disposed (e.g., printed, adhesively bonded) the optional dielectric layer 854, which is also disposed atop the dielectric layer 851. The various components of the power supply 849 are disposed atop the electrically-conductive layer 865, separate from the circuit assembly 820.

As discussed above, the circuit assembly 820 is layered atop the dielectric layer 854, which is disposed within the aperture 831 in the dielectric layer 851. Disposed atop the dielectric layer 854 is a circuit board 821 of the circuit assembly 820. The circuit board 821 can be electrically conductive or electrically non-conductive. If the circuit board 821 is a metal core type of board, the optional dielectric layer 854 can be applied before bonding to increase the separation between the metal base 815 and the circuit board 821, which will minimize or eliminate the capacitive coupling. If the circuit board 821 is made of a polymer-based material, the thickness of the circuit board 821 should be sufficiently large so as to minimize or eliminate the capacitive coupling. For example, the thickness of the circuit board 821 can be ≥0.002″, but it should be noted that this determination is dependent on the material used in the circuit board 821.

Atop the circuit board 821 in this example is disposed (e.g., printed) another dielectric layer 863 (also called an isolation plane 863). Finally, disposed atop the dielectric layer 863 are multiple electrically-conductive traces 855. The discrete components of the control circuit 840 of the circuit assembly 820 have electrically-conductive leads that are disposed on and make contact with the traces 855, using the traces 855 as electrical conductors to carry low voltage and/or control signals. One or more jumpers 825 are used to connect the control circuit 840 to the power supply 849, which is disposed atop the electrically-conductive layer 865. The combination of the traces 855, the dielectric layer 863, and the circuit board 821 make up the control circuit substrate 868, which can be electrically conductive or electrically non-conductive. Any of the printing techniques and/or materials described herein or known in the art can apply to any of the layers of the metal core circuit board assembly 810 of FIGS. 8A and 8B.

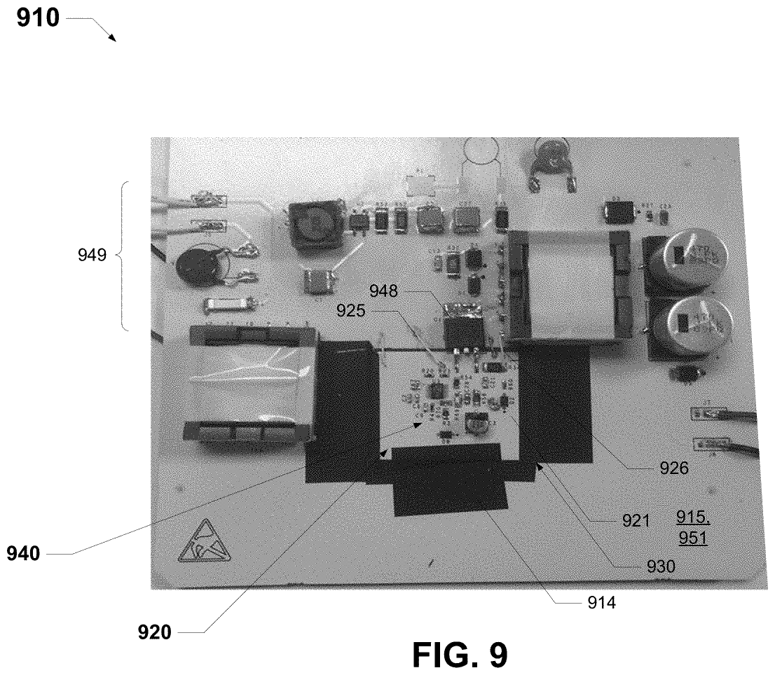

FIG. 9 shows a top view of a metal core circuit board assembly 910 that is a physical representation of the metal core circuit board assembly 810 of FIG. 8. The components of the metal core circuit board assembly 910 of FIG. 9 can be substantially the same as the corresponding components of the metal core circuit board assemblies discussed above. Referring to FIGS. 1 through 9, the metal core circuit board assembly 910 of FIG. 9 includes a metal base 915 that in this case has no aperture (e.g., aperture 331) that traverses the thickness of part of the metal base 915. Disposed on top of part of the metal base 915 is the circuit assembly 920. The circuit assembly 920 includes a circuit board 921 having a rectangular shape. The circuit assembly 920 has disposed thereon the control circuit 940, which is made of multiple discrete components (e.g., resistors, capacitors, diodes).

Disposed between the circuit assembly 920 and the rest (e.g., the power supply 949) of the metal core circuit board assembly 910 is a dielectric isolation plane 951. In this way, there is no direct physical contact (aside from jumpers, such as jumpers 925, 926) between the circuit assembly 920 and the rest (e.g., the power supply 949) of the metal core circuit board assembly 910. The power supply 949 in this case is made up of a number of discrete components (e.g., diodes, resistors, transistors, capacitors) that are disposed on the metal base 915.

Jumpers 925 (in this case electrical conductors) bridge the gap 930 formed between the circuit board 921 of the circuit assembly 920 and the power supply 949 disposed on the metal base 915, thereby providing electrical connectivity between the two. The circuit board assembly 910 in this case also includes a support 914 in the form of electrically non-conductive tape that is adhered to the top (and also possibly the bottom) surfaces of the metal base 915 and the circuit board 921 of the circuit assembly 920.

In the configuration shown in FIG. 9, the circuit board 921 of the circuit assembly 920 includes a metal substrate, and so the circuit board 921 becomes a functional, electronic shielding element of the circuit assembly 920 by maintaining a different polarity than the portion of the metal base 915 on which the power supply 949 is disposed. The control circuit 940 of the circuit assembly 920 needs to be shielded from the induced current that is capacitively coupled between the metal base 915 and the high-switched voltage of the power supply 949. The shield in this case is connected to the DC negative of the primary circuit power supply 949, which establishes a well-defined zero-volt reference (DC Ground) and is electrically isolated from the metal base 915. Any induced current in the DC ground shield will be sunk into the DC ground, and any resulting voltage will be clamped to zero volts.

Example embodiments show, describe, and contemplate various ways to isolate a power supply and/or control circuit from a circuit assembly of a metal core circuit board assembly for an electrical device. Example embodiments greatly reduce or eliminate capacitive coupling that occurs in the current art. By greatly reducing or eliminating capacitive coupling in the power and control circuitry used on metal-based circuit boards, the control signals can be unaltered, and the occurrence of false control signals can be eliminated.

Accordingly, many modifications and other embodiments set forth herein will come to mind to one skilled in the art to which example embodiments pertain having the benefit of the teachings presented in the foregoing descriptions and the associated drawings. Therefore, it is to be understood that example embodiments are not to be limited to the specific embodiments disclosed and that modifications and other embodiments are intended to be included within the scope of this application. Although specific terms are employed herein, they are used in a generic and descriptive sense only and not for purposes of limitation.

What is claimed is:

1. A metal core board assembly comprising:
a metal base layer upon which at least one electrical component is disposed; and
a circuit assembly disposed proximate to the metal base layer, wherein the circuit assembly is isolated from the metal base layer, wherein the circuit assembly is electrically coupled to the at least one electrical component,
wherein separating the circuit assembly from the metal base layer reduces effects of capacitive coupling on the circuit assembly.

2. The metal core board assembly of claim 1, wherein the metal base layer has an aperture that traverses therethrough, wherein the circuit assembly is disposed within the aperture without making direct contact with the metal base layer, forming a gap therebetween.

3. The metal core board assembly of claim 2, further comprising:
a support mounted on a bottom surface of the metal base layer, wherein the support covers the aperture, wherein the circuit assembly is disposed on the support, and wherein the support comprises an electrically non-conductive material.

4. The metal core board assembly of claim 3, further comprising:
a first dielectric layer disposed on a top surface of the metal base layer and the control circuit assembly.

5. The metal core board assembly of claim 4, further comprising:
an electrically conductive shield disposed atop the first dielectric layer.

6. The metal core board assembly of claim 5, further comprising:
a second dielectric layer disposed atop the electrically conductive shield.

7. The metal core board assembly of claim 6, further comprising:
at least one electrically conductive trace disposed atop the second dielectric layer.

8. The metal core board assembly of claim 2, further comprising:
at least one isolation tab disposed within the gap, wherein the at least one isolation tab is coupled to the circuit assembly and the metal base layer.

9. The metal core board assembly of claim 8, wherein the at least one isolation tab is removable.

10. The metal core board assembly of claim 8, wherein the at least one isolation tab provides an electrical connection between the circuit assembly and the at least one electrical component disposed on the metal base layer.

11. The metal core board assembly of claim 10, wherein the at least one electrical component disposed on the metal base layer comprises a power supply.

12. The metal core board assembly of claim 8, further comprising:
at least one jumper comprising a first end and a second end, wherein the first end is coupled to the circuit assembly, and wherein the second end is coupled to the at least one electrical component disposed on the metal base layer.

13. The metal core board assembly of claim 1, wherein the circuit assembly provides control to the at least one electrical component.

14. The metal core board assembly of claim 1, wherein the circuit assembly comprises multiple layers that are disposed atop each other.

15. The metal core board assembly of claim 14, wherein at least one of the layers of the multiple layers comprises a material that cures at a temperature that eliminates diffusion of metal into a layer having dielectric properties.

16. The metal core board assembly of claim 14, wherein at least one of the layers of the multiple layers comprises a polymer-based ink.

17. The metal core board assembly of claim 14, wherein at least one of the layers of the multiple layers is printed.

18. The metal core board assembly of claim 1, further comprising:
a first dielectric layer disposed on a top surface of the metal base layer; and
a second dielectric layer disposed on the first dielectric layer, wherein the circuit assembly is disposed atop the second dielectric layer.

19. The metal core board assembly of claim 18, wherein the first dielectric layer covers substantially all of the top surface of the metal base layer, wherein the second dielectric layer covers a first portion of the first dielectric layer, and wherein an electrically-conductive layer covers a remainder of the first dielectric layer.

20. The metal core board assembly of claim 18, wherein the circuit assembly comprises:
a circuit board disposed atop the second dielectric layer;
a third dielectric layer disposed atop the circuit board;
a plurality of electrically conductive traces disposed atop the third dielectric layer; and
a plurality of discrete electrical components disposed atop the plurality of electrically conductive traces.
